(19) United States
(12) Patent Application Publication
(10) Pub. No.: US 2011/0248139 A1
(43) Pub. Date: Oct. 13, 2011

(54) PORTABLE COMPUTER AIR CUSHION

(76) Inventor: Colin Filkow, Los Angeles, CA (US)

(21) Appl. No.: 13/082,819

(22) Filed: Apr. 8, 2011

(30) Foreign Application Priority Data
Apr. 8, 2010 (CN) 201020176016.5

(51) Int. Cl. H05K 7/20; H05K 7/00

(52) U.S. Cl. 248/346.03

(57) ABSTRACT

An air-filled cushion for portable computer devices. In the present invention, portable computer devices on top of the air cushion are secured by means of a strap to prevent shifting or falling off while being used. The design of the air cushion accords with ergonomic and height demands, so that the user can use the air cushion comfortably while sitting or lying down. Built-in open-cell mesh areas on the air cushion keep heat away from the lap and the portable computer device.

### BACKGROUND OF THE INVENTION

The present invention relates to an air cushion and more particularly to an inflatable air cushion for use with laptop computers, notebook computers, netbook computers, and tablet computers as well as other portable devices.

Portable computer devices such as laptop computers, notebook computers and tablet computers are now commonly in use. During use, these devices are normally placed on a person's lap while they are sitting or lying down. These devices however are uncomfortable on a person's lap because they are hard, and/or heavy, and/or get hot.

### BRIEF SUMMARY OF THE INVENTION

The present invention provides a novel air-cushioned ergonomic support for portable computer devices that solves the above inconveniences. The present invention is attractive, has a soft-touch finish and is engineered to provide a lightweight, cool and comfortable portable computing experience.

The present invention can be implemented through the following technical schemes:

The present invention has a securing strap with hook and loop fasteners (e.g. Velcro) to hold a portable computer device in place thereby preventing the portable computer device from shifting or falling off the present invention.

The present invention is further improved as follows: An air-inlet valve is located on the bottom of the air cushion under the securing strap. This is done to provide protection for the air-inlet valve and to hide the air-inlet valve from view. The air cushion is inflated easily at the air-inlet valve with an air-pump or by mouth and air is let out easily by squeezing the air-inlet valve.

The present invention is also further improved as follows: The top and bottom surfaces of the present invention have a central area inset with open-cell mesh to allow for ventilation. These mesh insets allow for heat from the portable computer device on the air cushion to dissipate through the mesh thereby cooling the portable computer device while keeping heat away from the user.

Compared with the prior art, the present invention has the following advantages: it's inflatable and air can be put in or let out as required; ergonomic design accords with comfort demands; it's a simple, lightweight structure that can be used easily anywhere and in any position. Furthermore, portable computer devices on top of the present invention are secured by a transparent securing strap with hook and loop fasteners at its ends. The securing strap is held in place by a sleeve on the bottom, but the securing strap is not attached directly to the air cushion. The built-in mesh ventilation system is beneficial for portable computer heat dissipation and user comfort.

### BRIEF DESCRIPTION OF THE DRAWINGS

FIG. 1 is a top view of the present invention.

FIG. 2 is a bottom view of the present invention.

### DETAILED DESCRIPTION

Embodiments of the present invention will be described in detail below with reference to the accompanying drawings.

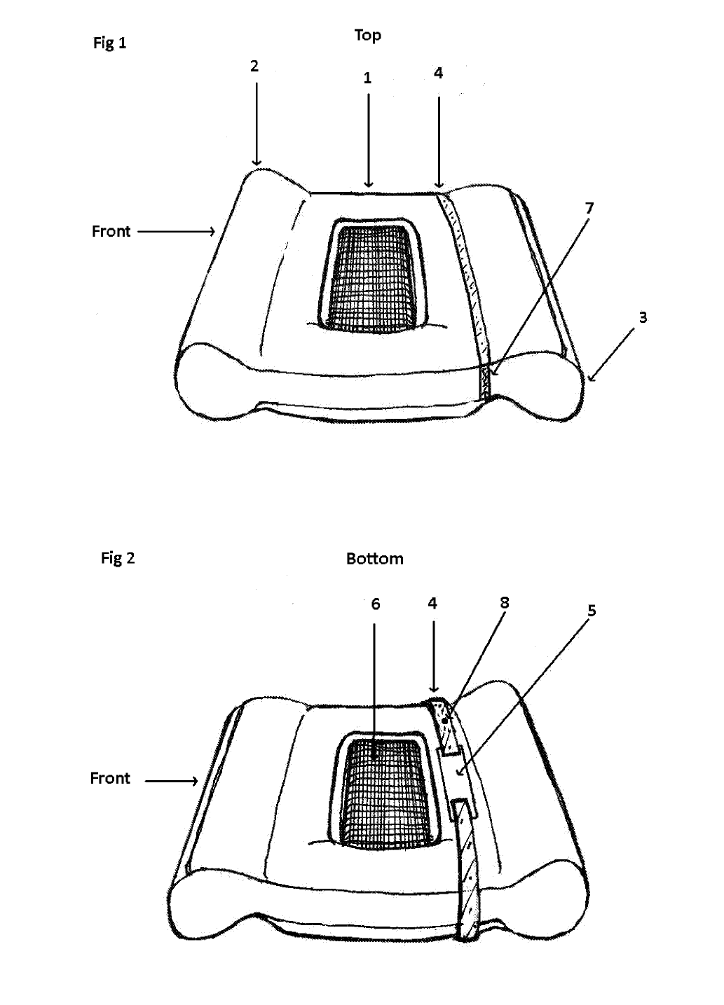

As shown in FIG. 1, the present invention (1) includes an air-filled cushion designed to comfortably support and cool portable computer devices. The present invention is filled with air so it is very lightweight yet substantial enough to support a portable computer. The present invention is for use on a person's lap or on a desk, table, floor, sofa, bed, chair, at home, work, school, or during travel. The present invention is totally portable because its air can be let out, and when not filled with air, the present invention is a small fraction of the size it is when inflated.

The front of the present invention has a raised contour shape that serves as a Wrist Rest (2). The back of the present invention has the same contour shape as the front but the back contour shape faces down to serve as a riser (3) on the user's legs to help keep the air cushion level. The front and back of the present invention are mirror images of each other, only reversed. The lower top back allows for access to plug-ins and discs. The sides of the air cushion are level with the body of the air cushion to allow for heat dissipation from portable computers that vent out the side. The present invention has a simple structure and is versatile, adaptable and easy to use.

As shown in FIG. 2, the present invention incorporates a securing strap (4) that slides through a sleeve (5) that is affixed to the air cushion on the bottom at the back. The securing strap wraps over the portable computer device parallel and close to the portable computer's screen. The securing strap is flexible and adjustable and will accommodate all laptops, notebooks and tablets. The securing strap prevents the device on top from tipping backwards or falling frontwards or sideways. Two securing straps are required for securing tablet computers.

The securing strap is made from a soft but strong material that is transparent so users can see lights or press buttons underneath it. Hook and loop fasteners (7) at both ends of the securing strap attach to each other on the side and on the bottom of the air cushion thereby holding the portable computer device securely in place. The sleeve (5) facilitates easy positioning of the securing strap.

The securing strap through the sleeve design in the present invention allows for the strap to be easily positioned by simply sliding it through the sleeve in either direction before the air cushion is fully inflated. Once the air cushion is fully inflated, friction stops the strap from sliding, thus ensuring a secure hold. Because the strap is not attached directly to the air cushion it doesn't pull on or put any outward stress on any seams of the air cushion.

The present invention has built-in ventilation to keep heat away from the lap and the portable computer device. The present invention incorporates an open-cell mesh inset (6) in the center area of the top and the bottom of the air cushion to allow heat from the portable computer device on top to dissipate its heat out through the mesh.

The mesh provides critical cooling for the portable computer which helps promote optimum computer performance and extend the life of the computer's components.

The present invention has an air-inlet valve (8) on the bottom of the air-cushion. The air cushion is easily inflated and deflated. The air cushion is inflated with an air-pump or by mouth and air is let out by simply opening and squeezing the air-inlet valve.

The present invention includes a mini air-pump and a carrying case specially-made for it. The carrying case is lightweight, convenient and protects the air cushion when it is being transported without air.

The above embodiments are preferable for the present invention, but the present invention is not limited to these embodiments. Any other changes, modifications, substitutions, combinations and simplifications made without departing from the spirit and principle of the present invention shall be regarded as equivalents of the present invention and shall fall within the claimed scope of the present invention.

1. An ergonomically-designed air cushion for use with portable computer devices (1).

2. The air cushion of claim 1 further includes a transparent securing strap (4) that is not directly attached to the air cushion thereby eliminating stresses to the seams.

3. The air cushion of claim 2 further includes a sleeve (5) that allows the securing strap to be positioned easily and pulled tight without putting outward stress on the air cushion's seams.

4. The air cushion of claim 1, wherein the central areas on the top and bottom of the air cushion (6) are formed with open-cell mesh for portable computer heat dissipation and user comfort.

5. The air cushion of claim 4 further includes an air-inlet valve (8) on the bottom of the air cushion which is covered and protected by the securing strap.

6. The air cushion of claim 4 further includes hook and loop fasteners (e.g. Velcro) on the securing strap are used to attach the two ends (7) of the securing strap together on the side and on the bottom of the air cushion.
